(19) United States
(12) Patent Application Publication
(10) Pub. No.: US 2004/0076043 A1
(43) Pub. Date: Apr. 22, 2004

(54) Reliable and secure updating and recovery of firmware from a mass storage device

(75) Inventors: Daniel A. Boals, Irvine, CA (US); Dao B. Demming, Aliso Viejo, CA (US); Kraig Lane, Castaic, CA (US)

Correspondence Address: Claudia Cameron, Phoenix Technologies Ltd., 411 East Plumeria Drive, San Jose, CA, 95134, US

(73) Assignee: Phoenix Technologies Ltd.

(21) Appl. No.: 10/274,759

(22) Filed: Oct. 21, 2002

(51) Int. Cl. G11C 29/00

(52) U.S. Cl. 365/200

(57) ABSTRACT

Systems, methods, and software that update or recover system firmware (BIOS) of a computer system using a utility running from a protected area of a mass storage device. This avoids the standard operating system environment and removes the possibility of tampering or deletion of required files. Files containing a copy of system firmware (BIOS) and a firmware update utility for writing to the system EEPROM or flash ROM are transferred to the mass storage device. Once the files are transferred, the area on the mass storage device containing these files are protected in a Host Protected Area, for example. After protecting or locking this area of the mass storage device, the system firmware or boot utility either boots the standard operating system or runs the firmware update utility from the Host Protected Area in recovery mode if the firmware is corrupted. This allows the firmware update utility to run in an environment outside of and independent of the standard operating environment of the computer system. In the event that an end user needs to update the system firmware, an application is used to provide the firmware update utility with a new firmware image. This application then requests that the system boot the update utility on next boot.

### BACKGROUND

The present invention relates generally to computer systems and related methods, and more particularly, to systems, methods, and software that reliably and securely update and recover system firmware from a mass storage device.

There are a number of utilities that will update system firmware of a personal computer from an unprotected area of the disk running in the environment of the systems main operating system. The utility could be run from a floppy drive containing DOS. However, this requires that the end user be able to generate a bootable floppy drive.

A “Boot Block” is a piece of main system firmware (BIOS) that is never updated. The purpose of the Boot Block is to determine whether other portions of the system's firmware (BIOS) are corrupt. After determining the system firmware is ok, the Boot Block passes control to the main system firmware for the remainder of POST (Power-On Self-Test) initialization. On the other hand, if the system's firmware is corrupt, the Boot Block provides a mechanism to recover the system firmware to a known working version, by loading required utilities and files from some form of storage media or floppy device.

A Protected Area Run Time Extension Services Standard (ANSI BSR NCITS-346) provides a mechanism for storing data in the private area, called a service area, on a hard disk drive. This standard also provides a method for booting an operating system from a service area.

There are a number of disadvantages exhibited by the known prior art. For example, if the process of programming a system firmware into EEPROM or flash ROM is interrupted or terminated prematurely the system could be left unusable. There are a number of possibilities that could cause one of these two events.

Current utilities must execute in the environment of the main operating system under which the utility may not have enough control to prevent task switching. This could interfere with time critical events required of programming the EEPROM or flash ROM device. Another possible problem is that the operating system has control over system power. If the operating system power management scheme determines that it needs to put the system to sleep or turn the system off, it could remove power prematurely, terminating the programming process.

Most crisis recovery scenarios require a user to create a floppy disk containing the required recovery files and utilities in advance. Floppy devices have a relatively small amount of space and Firmware images alone are approaching the size of a floppy disk. This leaves little room for future expansion.

Because the file system of the main operating system may be unknown at the time the system is manufactured, or may be changed after the system is shipped, it is not possible to assume the crisis recovery files would be on the hard disk drive. Even if the file system is known, its complexity may require more code than will fit in the Boot Block area of the EEPROM or flash ROM.

In addition, other operating system file systems may contain intellectual property that must be licensed if code to access it is contained in the Boot Block. Furthermore, placing crisis recovery files in the file system of the main operating system also exposes them to malicious software (such as a virus) that may alter or delete the files.

It is therefore an objective of the present invention is to provide for systems, methods, and software that reliably and securely update and recover system firmware from a mass storage device.

### SUMMARY OF THE INVENTION

To accomplish the above and other objectives, the present invention provides for systems, methods, and software for updating or recovering system firmware (BIOS) of a computer system, such as a personal computer, using a utility running from a protected area of a mass storage or nonvolatile storage device, such as a hard disk drive, for example. This avoids the standard operating system environment and removes the possibility of tampering or deletion of required files. In the event the firmware is corrupted, the computer system is placed in recovery mode and a utility is run from the protected area to restore a known working version of the system firmware.

The present invention may be implemented as follows. During manufacturing of the computer system, files containing a copy of system firmware (BIOS) and a firmware update utility for writing to the system EEPROM or flash ROM are transferred to the mass storage device or hard disk drive. Once the files are transferred, the area on the hard disk drive containing these files can be protected, such as by using a “Host Protected Area” feature set of the ATA specification, or other available mechanism.

After protecting or locking this area of the hard disk drive, the system firmware or boot utility either boots the standard operating system or runs the firmware update utility from the Host Protected Area. This allows the firmware update utility to run in an environment outside of and independent of the standard operating environment of the computer system.

In the event that an end user needs to update the system firmware, an application is used to provide the firmware update utility with a new firmware image. This application then requests that the system boot the update utility on next boot.

### BRIEF DESCRIPTION OF THE DRAWINGS

The various features and advantages of the present invention may be more readily understood with reference to the following detailed description taken in conjunction with the accompanying drawing figures, wherein like reference numerals designate like structural elements, and in which:

FIG. 1 is block diagram illustrating an exemplary personal computer system that embodies a method in accordance with the principles of the present invention that reliably and securely updates and recovers system firmware from a mass storage device; and

FIG. 2 is a flow diagram illustrating an exemplary method and software code in accordance with the principles of the present invention.

### DETAILED DESCRIPTION

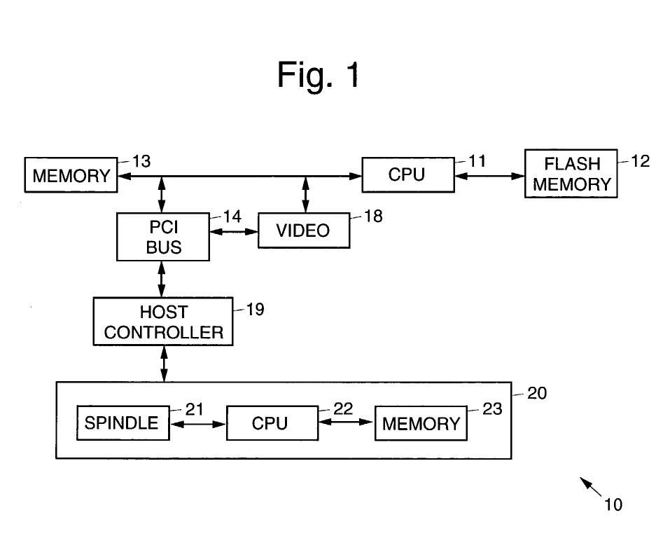

Referring to the drawing figures, FIG. 1 is block diagram illustrating an exemplary computer system 10, such as a personal computer system 10, that embodies a method 30 that reliably and securely updates and recovers system firmware from a mass storage device 20 comprising a secondary nonvolatile storage device 20. The computer system 10 comprises a central processing unit (CPU) 11 that is coupled to a critical nonvolatile storage device 12. The critical nonvolatile storage device 12 may be flash memory, a read only memory (ROM), a programmable read only memory (PROM), an erasable programmable read only memory (EPROM), an electrically erasable programmable read only memory (EEPROM), or other device or technology that the CPU 11 can use to execute an initial set of instructions.

The CPU 11 is also coupled to a system memory 13, such as a random access memory 13. The CPU 11 may be coupled to the secondary nonvolatile storage device 20 by way of a system bus 14, such as a Peripheral Component Interconnect (PCI) bus 14, for example. The secondary nonvolatile storage device 20 may be a hard disk drive, a compact disk (CD) drive, a digital video disk (DVD) drive, a floppy disk drive, a Zip drive, a SuperDisk drive, a magneto-optical disk drive, a Jazz drive, a high density floppy disk (HiFD) drive, flash memory, read only memory (ROM), programmable read only memory (PROM), erasable programmable read only memory (EPROM), electrically erasable programmable read only memory (EEPROM), or any other device or technology capable of preserving data in the event of a power-off condition.

A first portion of the critical nonvolatile storage device 12 stores initialization code that is operative to initializes the CPU 11 and the system memory 13. A second portion of the critical nonvolatile storage device 12 stores a dispatch manager that contains a list of tasks, which must execute to fully initialize the computer system 10. The dispatch manager is operative to selectively load and iteratively execute a number of tasks relating to complete initialization of the computer.

In operation, when the computer system 10 is turned on, the initialization code is run to initialize the CPU 11 and the system memory 13. The dispatch manager is then loaded into the system memory 13. The dispatch manager executes the list of tasks contained therein to cause all required firmware (BIOS modules) to be loaded into the system memory 13 and must be executed.

The dispatch manager determines whether each required BIOS module in the system memory 13, and if it is not, finds, loads and executes each required BIOS module. The BIOS modules may be located in the critical nonvolatile storage device 12 (flash memory) or in the secondary nonvolatile storage device 20, including any of the critical or secondary nonvolatile storage devices 20 identified above.

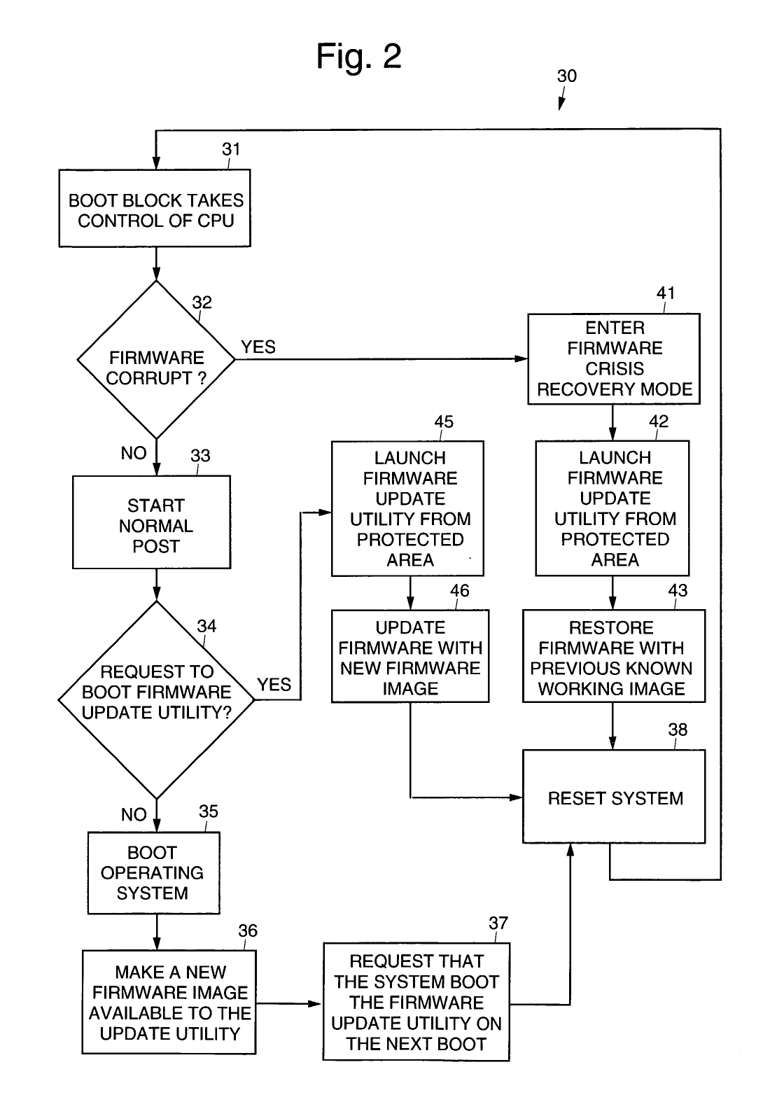

Referring now to FIG. 2, it is a detailed flow diagram illustrating an exemplary method 30 and software code in accordance with the principles of the present invention. The exemplary method 30 comprises the following steps.

The computer system 10 is booted and the boot block takes control 31 of the CPYU 11. A determination 32 is made if the firmware is corrupt. If the firmware is not corrupt (No), normal POST (Power-On Self-Test) procedures are run 33. Then, a request is made to boot 34 a firmware update utility. If the firmware update utility 34 is not run (No), the operating system is booted 35, and a new firmware image is made available 36 to the update utility. A request 37 is made that the system boot the firmware update utility on the next boot of the computer system 10. The computer system is then reset 38.

If it is determined 32 that the firmware is corrupt (Yes), a firmware crisis recovery mode is entered 41. A firmware update utility is launched 42 from a protected area. The firmware is restored 43 with a known previously working image. The computer system is then reset 38.

If the firmware update utility 34 is run (yes), the firmware update utility is launched 45 from the protected area. The firmware is updated 46 with a new firmware image. The computer system is then reset 38.

Thus, during manufacturing of the computer system 10, files containing a copy of system firmware (BIOS) and the firmware update utility to write to the system EEPROM or flash ROM are transferred to the hard disk drive 20. Once the files are transferred, the area on the hard disk drive 20 containing these files is protected, such as by using a “Host Protected Area” feature set of the ATA specification, or other mechanism. After protecting or locking this area of the hard disk drive 20, the system firmware or boot utility either boots the standard operating system or runs the firmware update utility from the Host Protected Area. This allows the utility to run in an environment outside of and independent of the standard operating environment of the personal computer 10.

In the event that an end user needs to update the system firmware, an application is used to provide the firmware update utility with a new firmware image. This application then requests that the system boot the update utility on next boot. The present invention implements this.

There are several advantages to updating or restoring a system's firmware from a protected area of a hard disk drive 20.

A firmware update utility that can run from a protected area of the hard disk drive 20 can prevent corruption or tampering of the new system files before updating. Also, a crisis recover floppy does not need to be created and maintained in advance. This makes the process of recovering more reliable and simpler for the end user.

The present method of updating system firmware provides an operating environment free of normal operating system task swapping and/or power management interruptions that could cause the update to fail and leave the system unusable. This controlled environment provides much greater control over the critical timing of the EEPROM or flash ROM programming process.

Because the protected area of the hard disk is generally not accessible by the end user and the main operating system, the files can be laid out as needed without fear of deletion or tampering, this can reduce the complexity of the firmware update utility as it can know in advance exactly where on the hard disk the required files are. This is useful due to the reduced capabilities resulting from the relatively small amount of EEPROM or Flash ROM space that is provided for the Boot Block.

Certain features of the present invention are believed to be new and novel. For instance, the present invention protects the firmware update process from being interrupted by the operating system and the required files from being deleted or tampered with by the end user or malicious software. The present invention also provides a mechanism for firmware recovery that is simpler for the end user, because they do not have to create and maintain a crisis recover floppy disk.

The present invention also allows the firmware and utility files to be laid out on the hard disk drive 20 in a way that is simpler to access by the boot block than having them exist in the file system of the main operating system's. This allows the recovery code to be simpler. Today recovery from a corrupt ROM is not even possible from a proprietary file system such as the NT file system (NTFS), which is a file system for the Windows NT operating system developed by Microsoft.

Thus, systems, methods, and software that implement embedded controller firmware updating have been disclosed. It is to be understood that the above-described embodiments are merely illustrative of some of the many specific embodiments that represent applications of the principles of the present invention. Clearly, numerous and other arrangements can be readily devised by those skilled in the art without departing from the scope of the invention.

What is claimed is:

1. A system that provides for embedded controller firmware updating, comprising:
(1) a central processing unit (CPU)
(2) a system memory coupled to the CPU;
(3) a critical nonvolatile storage device coupled to the CPU that stores initialization code comprising a basic input/output system (BIOS) that is operative to initialize the CPU and the system memory and a dispatch manager that contains a list of tasks, that execute to fully initialize the computer system, which dispatch manager is operative to selectively load and iteratively execute a number of tasks relating to initialization of the computer;
(4) a secondary nonvolatile storage device coupled to the CPU that preserves data in the event of a power-off condition; and
(5) software disposed on the critical nonvolatile storage device that provides embedded controller firmware updating that comprises:
a code section that comprises embedded controller firmware;
a code section that is part of the BIOS that comprises a flash utility;
a code section that boots the computer;
a code section that runs the flash utility during booting of the computer to write a new firmware image and an embedded controller update algorithm or procedure into a system BIOS storage area of the computer;
a code section that re-boots the computer; and
a code section that causes the system BIOS to run the update algorithm or procedure during re-booting of the computer, which update algorithm or procedure writes the new firmware image into an embedded controller firmware storage area of the computer.

2. The system recited in claim 1 wherein the flash utility comprises a flash utility that runs under a Windows operating system.

3. A method, for use with a computer system having a basic input/output system (BIOS) and an operating system, that provides embedded controller firmware updating, comprising the steps of:
providing embedded controller firmware as part of the BIOS;
providing a flash utility as part of the BIOS;
booting the personal computer system;
during booting, causing the flash utility to write a new firmware image and a embedded controller update algorithm into a system BIOS storage area of the personal computer system;
re-booting the personal computer system;
during re-booting, causing the system BIOS to run the update algorithm; and
causing the update algorithm to write the new firmware image into an embedded controller firmware storage area of the personal computer system.

4. The method recited in claim 2 wherein the operating system is a Windows operating system, and the flash utility is one that runs under a Windows operating system.

5. Software, for use with a computer system having a basic input/output system (BIOS) and an operating system, that provides embedded controller firmware updating, comprising:
a code section that comprises embedded controller firmware;
a code section that is part of the BIOS that comprises a flash utility;
a code section that boots the computer;
a code section that runs the flash utility during booting of the computer to write a new firmware image and an embedded controller update algorithm or procedure into a system BIOS storage area of the computer;
a code section that re-boots the computer; and
a code section that causes the system BIOS to run the update algorithm or procedure during re-booting of the computer, which update algorithm or procedure writes the new firmware image into an embedded controller firmware storage area of the computer.

6. The software recited in claim 5 wherein the operating system is a Windows operating system, and the flash utility is one that runs under a Windows operating system.
